(19) United States
(12) Patent Application Publication
(10) Pub. No.: US 2024/0403522 A1
(43) Pub. Date: Dec. 5, 2024

(54) MICROFLUIDICS THERMAL MANAGEMENT FLOW PATTERNS AND SCHEMAS

(71) Applicant: Microsoft Technology Licensing, LLC, Redmond, WA (US)

(72) Inventors: Bharath RAMAKRISHNAN, Bellevue, WA (US); Husam Atallah ALISSA, Redmond, WA (US); Vaidehi ORUGANTI, Kirkland, WA (US); Maria Leena Kyllikki VIITANIEMI, Seattle, WA (US); Winston Allen SAUNDERS, Seattle, WA (US)

(21) Appl. No.: 18/204,042

(22) Filed: May 31, 2023

(51) Int. Cl. G06F 30/28; G06F 1/20; G06F 30/17

(52) U.S. Cl. CPC G06F 30/28; G06F 1/206; G06F 30/17

(57) ABSTRACT

A system may model a thermal management demand of a heat-generating component on an outer surface of the heat-generating component as a heat generation map. A system may select an initial channel design based on the heat generation map. A system may evaluate the initial channel design, wherein evaluated metrics include at least pressure drop and thermal resistance of the channel design. A system may change at least one parameter of the initial channel design based on the evaluated metrics to create a refined channel design. A system may form at least one thermal element in or on the outer surface of the heat-generating component according to the refined channel design.

### BACKGROUND

Thermal management of processors, memory, and other heat-generating components of high-performance computing devices removes relatively large quantities of heat from a smaller area or volume. Conventional thermal management systems connect a working fluid to the heat-generating components through a metallic heat sink or other interface. Reducing the number of thermal interfaces can improve thermal management performance.

### BRIEF SUMMARY

In some aspects, the techniques described herein relate to a method for manufacturing a thermal management device, the method including: modeling a thermal management demand of a heat-generating component on an outer surface of the heat-generating component as a heat generation map; selecting an initial channel design based on the heat generation map; evaluating the initial channel design, wherein evaluated metrics include at least pressure drop and thermal resistance of the channel design; changing at least one parameter of the initial channel design based on the evaluated metrics to create a refined channel design; and forming at least one thermal element in or on the outer surface of the heat-generating component according to the refined channel design.

In some aspects, the techniques described herein relate to a device for thermal management including: a heat-generating component having an outer surface; a body connected to the heat-generating component; a microfluidic cooling volume contacting the outer surface and defined by the outer surface and the body; and at least one microfluidic thermal element positioned on the outer surface according to a channel design based at least partially on a heat generation map of the outer surface and in the microfluidic volume to transfer heat from the heat-generating component to a working fluid in the microfluidic volume.

In some aspects, the techniques described herein relate to a method for manufacturing a processing unit, the method including: modeling a thermal management demand of a processing unit on an outer surface of a die of the processing unit as a heat generation map; selecting an initial channel design for the outer surface of the die; evaluating the initial channel design, wherein evaluated metrics of the initial channel design include at least pressure drop and thermal resistance of the initial channel design; changing at least one parameter of the initial channel design based on the evaluated metrics to create a refined channel design; evaluating the refined channel design, wherein evaluated metrics of the refined channel design include at least pressure drop and thermal resistance of the refined channel design; changing at least one parameter of the refined channel design based on the evaluated metrics of the refined channel design to create another refined channel design; and forming at least one thermal element in or on the outer surface of the die according to the another refined channel design.

This Summary is provided to introduce a selection of concepts in a simplified form that are further described below in the Detailed Description. This Summary is not intended to identify key features or essential features of the claimed subject matter. Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a cross-sectional perspective view of a 2.5-dimensional processor and thermal management device, according to at least some embodiments of the present disclosure.

FIG. 2 is a cross-sectional perspective view of a three-dimensional processor and thermal management device, according to at least some embodiments of the present disclosure.

FIG. 3 is a heat generation map of a surface area of a heat-generating component, according to at least some embodiments of the present disclosure.

FIG. 4 is a heat flow map of a portion of the heat generation map of FIG. 3, according to at least some embodiments of the present disclosure.

FIG. 5 is a flowchart illustrating a method of designing and manufacturing a thermal management device, according to at least some embodiments of the present disclosure.

FIG. 6 is an example of designing and manufacturing a thermal management device for a heat-generating component, according to at least some embodiments of the present disclosure.

FIG. 7 is a schematic representation of a machine learning model, according to at least some embodiments of the present disclosure.

FIG. 8 is a perspective view of a subtractive manufacturing of a thermal management device, according to at least some embodiments of the present disclosure.

FIG. 9 is a perspective view of an additive manufacturing of a thermal management device, according to at least some embodiments of the present disclosure.

### DETAILED DESCRIPTION

The present disclosure relates generally to the design, manufacturing, and operation of thermal management devices. More particularly, the present disclosure relates to the design, manufacturing, and operation of a thermal management device with a working fluid that receives heat from a heat-generating component. The working fluid flows away from the heat-generating component and carries the heat away from the heat-generating component. In at least one example, the working fluid is a liquid working fluid that receives heat from the heat-generating component at a thermal interface, and the liquid working fluid flows away from the thermal management device to a heat exchanger or other device to exhaust the heat from the liquid working fluid to atmosphere or other heat dump.

In some embodiments, at least a portion of the thermal management device is integrally formed with the heat-generating component. In some embodiments, the thermal management device is integrally formed with a surface of the heat-generating component. In some examples, the thermal management device is formed in a surface of the heat-generated component through a subtractive process to remove material from the surface of the heat-generating component and/or form one or more thermal elements in the surface of the heat-generating component. In some examples, the thermal management device is formed on a surface of the heat-generating component through an additive process to adhere, sinter, or otherwise bond thermal elements to the surface of the heat-generating component. In some embodiments, the thermal management device is formed through a combination of subtractive and additive processes, such as removing material from a surface of the heat-generating component and adhering, sintering, or otherwise bonding material to the outer surface (or the exposed surface after removing material from the outer surface) to form one or more thermal elements in or on the surface of the heat-generating component.

In some embodiments, the thermal management device is thermally connected to a heat-generating component. As used herein, the term “thermally connected” refers to a connection between two components that facilitates the transfer of heat between the two components. Two thermally connected components may be in direct contact (e.g., without any intervening material). Two thermally connected components may have one or more thermal connectors between them. The thermal connector may be a thermally conductive material, or a material that facilitates the transfer of heat through its mass. For example, two thermally connected components may include a thermal interface material (TIM) between the two components. A TIM may be a material, such as a flowable paste formed from thermally conductive materials, that may be inserted between two components to reduce or eliminate the presence of air gaps and other insulating material. In some embodiments, two thermally connected components may be separated from each other. For example, a thermal connector such as a heat pipe may thermally connect two components across a distance.

In some embodiments, the one or more thermal elements are formed in or on the thermal management device based at least partially on a flow design or schema generated from a thermal demand map. In some embodiments, a heat-generating component produces heat in a non-uniform distribution at the outer surface of the heat-generating component. The thermal elements positioned in or on the surface of the heat-generating component are positioned to efficiently remove the heat produced at the surface of the heat-generating component. In some embodiments, one or more channels formed by or between the thermal elements direct a working fluid across the surface and/or away from the surface to remove heat from the hotter portions of the surface and/or toward cooler portions of the surface. In some embodiments, one or more channels formed by or between the thermal elements direct a working fluid across the surface through a cooling volume from an inlet to an outlet of the cooling volume. In some examples, the inlet and outlet are defined by a working fluid manifold positioned on or integrated in the thermal management device.

In some embodiments, a heat-generating component is a processing unit. A processing unit includes a central processing unit, a graphics processing unit, a physics processing unit, a network processing unit, an audio processing unit, or other processing units including one or more processing cores, volatile memory (e.g., cache), non-volatile memory, input-output (I/O) components, or other components of the processing units. The components of the processing unit produce heat. The amount of heat and the dispersion of the heat at the surface varies according to the topology of the components of the processing unit. A heat-generation map of the outer surface of the heat-generating component can allow for efficient design and construction of a thermal management device for the heat-generating component.

While the present disclosure describes embodiments of thermal management devices in relation to processing units, it should be understood that the embodiments of systems and methods for designing, manufacturing, operating, and combinations thereof thermal management devices are applicable to other heat-generating components, such as power supplies, computer system memory (volatile and non-volatile), networking devices, motherboard components, communication bridges, etc.

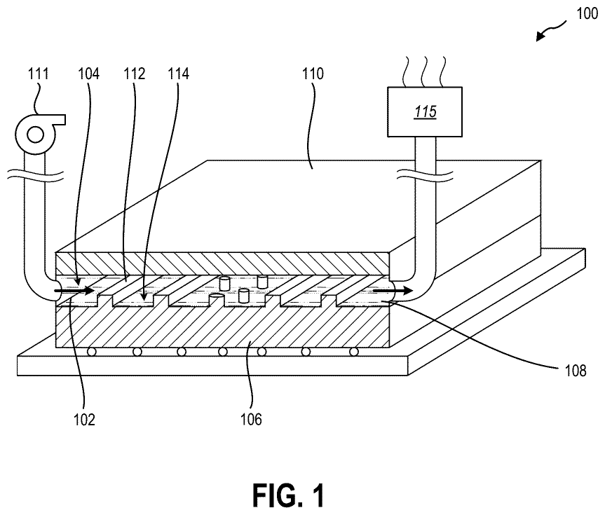

In at least some embodiments, a thermal management device includes a cooling volume that is a microfluidic volume in or on an outer surface of a processing unit die and/or between a first die and a second die of a stacked-die processing unit. In some embodiments, a thermal management device is thermally connected to and/or integrated with a 2.5-dimensional (2.5D) processing unit in which the microfluidic volume is positioned in or on an upper surface of a die of a processing unit, such as illustrated in the side cross-sectional view of FIG. 1.

In some embodiments, the thermal management device 100 includes a working fluid 102 positioned in a cooling volume 104 contacting or thermally connected to a heat-generating component 106. In some embodiments, the cooling volume 104 is contacting an outer surface 108 of the heat-generating component 106. In some embodiments, the cooling volume 104 is substantially enclosed within a body 110 of the thermal management device 100, where the body 110 thermally connects the cooling volume 104 to an outer surface 108 of the heat-generating component 106. In some embodiments, the body 110 is thermally connected to an outer surface 108 of the heat-generating component 106 by a TIM. In some embodiments, the working fluid 102 is flowed or pressurized into the cooling volume 104 by a pump 111.

In some embodiments, the thermal management device 100 includes and/or is integrated with the outer surface 108 of the heat-generating component 106. For example, the body 110 of the thermal management device 100 defines a portion of the cooling volume 104 and the outer surface 108 of the heat-generating component 106 defines another portion of the cooling volume 104. The thermal management device 100 therefore, in some embodiments, includes one or more thermal elements 112 located in or on the surface of the heat-generating component 106. In some embodiments, one or more thermal elements 112, such as pins, fins, rods, or other positive thermal elements are positioned on an outer surface 108 of the heat-generating component 106. In some embodiments, one or more channels 114, recesses, voids, or other negative thermal elements between pins, fins, rods, etc., are positioned in an outer surface 108 of the heat-generating component 106. In some embodiments, one or more positive thermal elements are positioned in the negative thermal elements. For example, a plurality of parallel channels 114 (e.g., negative thermal elements) etched in the outer surface 108 define fins or other positive thermal elements therebetween without adding material to the outer surface 108 of the heat-generating component 106. In some embodiments, the hot working fluid 102 exits the cooling volume 104 and exhausts heat at a heat exchanger 115 or other radiator.

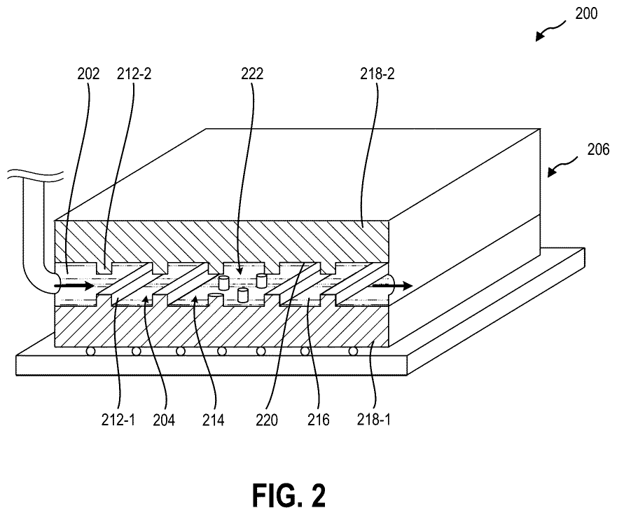

In some embodiments, a thermal management device 200 is thermally connected to and/or integrated with a 3-dimensional (3D) heat-generating component 206 (i.e., processing unit) in which the microfluidic cooling volume 204 is positioned in or on an upper surface 216 of a first die 218-1 of the 3D heat-generating component 206 and in or on a lower surface 220 of a second die 218-2 of the 3D heat-generating component 206, such as illustrated in the side cross-sectional view of FIG. 2.

In some embodiments, the cooling volume 204 is substantially enclosed within the 3D heat-generating component 206 between the first die 218-1 and the second die 218-2. In some embodiments, the cooling volume 204 includes one or more thermal elements 212-1, 212-2 located in or on the upper surface 216 of a first die 218-1 of the 3D heat-generating component 206 and/or in or on a lower surface 220 of a second die 218-2 of the 3D heat-generating component 206. In some embodiments, a first thermal element 212-1 located in or on the upper surface 216 of a first die 218-1 of the 3D heat-generating component 206 contacts a second thermal element 212-2 located in or on a lower surface 220 of a second die 218-2 of the 3D heat-generating component 206 to form a closed channel 214. In some embodiments, a first thermal element 212-1 located in or on the upper surface 216 of a first die 218-1 of the 3D heat-generating component 206 and/or a second thermal element 212-2 located in or on a lower surface 220 of a second die 218-2 of the 3D heat-generating component 206 protrude into an open portion 222 of the cooling volume 204 without contacting one another, allowing working fluid 202 to flow between the first thermal element 212-1 and the second thermal element 212-2 in the cooling volume 204 while the first thermal element 212-1 and the second thermal element 212-2 direct flow of the working fluid 202 relative to the upper surface 216 of a first die 218-1 of the 3D heat-generating component 206 and/or the lower surface 220 of a second die 218-2 of the 3D heat-generating component 206, respectively.

In some embodiments, the working fluid 202 of the thermal management device 200 (of any other embodiments of a thermal management device described herein, such as the thermal management device 100 of FIG. 1) is a liquid working fluid. In some embodiments, the working fluid 202 is a gaseous working fluid. In some embodiments, the working fluid 202 is a substantially single-phase working fluid 202. For example, a single-phase working fluid 202 remains in a single physical phase (e.g., a liquid) throughout the operation of the thermal management device 200. In some embodiments, the working fluid 202 is a two-phase working fluid 202. For example, a two-phase working fluid 202 transitions between physical phases (e.g., liquid to gas; gas to liquid) as heat is received or exhaust from the working fluid 202 during operation of the thermal management device 200.

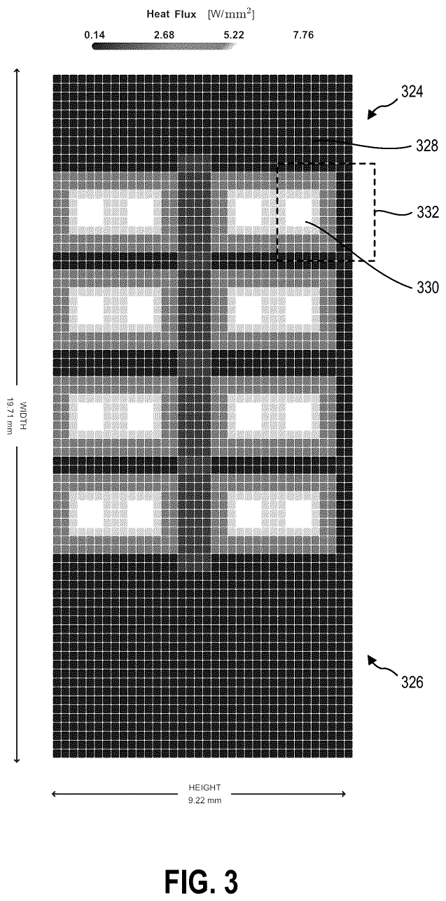

As described herein, a system and method of designing and manufacturing the thermal elements of a thermal management device, according to at least some embodiments of the present disclosure, includes creating a heat generation map of the heat-generating component. FIG. 3 is a top view of a heat generation map 324 of a processing unit, such as the 2.5D processing unit of FIG. 1, a die of the 3D processing unit of FIG. 2, or another processing unit.

In some embodiments, the heat generation map 324 maps the heat generation of a heat-generating component (such as any embodiment of heat-generating components described herein) across a surface area 326 of the heat-generating component. In some examples, the surface area 326 is that of an outer surface of the heat-generating component, such as described in relation to FIG. 1. In some examples, the surface area 326 is an upper surface or lower surface of the heat-generating component or portion of the heat-generating component, such as described in relation to FIG. 2. In some embodiments, the heat generation map 324 includes low-temperature regions 328 and high-temperature regions 330. It should be understood that low-temperature and high-temperature are considered relative to one another, and, depending on the demands and operating conditions of a heat-generating component, the nominal temperature of low-temperature regions 328 and high-temperature regions 330 can vary.

In some embodiments, a thermal management device flows a working fluid across the surface of the heat-generating component to move heat from the high-temperature regions 330 toward the low-temperature regions 328. The working fluid thereby reduces the temperature of the high-temperature regions 330. The working fluid is circulated to the surface area 326 of the heat-generating component through one or more inlets of the thermal management device and circulated from the surface area 326 of the heat-generating component through one or more outlets of the thermal management device. In some embodiments, the thermal management device flows a working fluid from the one or more inlets, across the surface of the heat-generating component to move heat from the high-temperature regions 330 toward the low-temperature regions 328, and out through the one or more outlets.

While FIG. 3 illustrates a heat generation map 324 of the surface area 326, in some embodiments, mapping or modeling a thermal management demand of the heat-generating component includes creating or obtaining a power consumption map of the heat-generating component. For example, different cores, memory, connections, or components of the heat-generating component consume different amounts of power during operation. In some embodiments, the heat generation of the heat-generating component is proportional to the power consumption of the different regions or components of the heat-generating component. A power consumption map allows for a calculation or approximation of heat generation during operation.

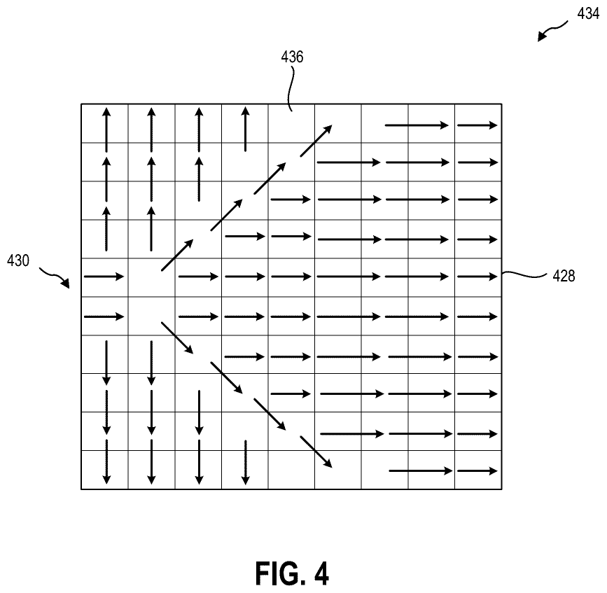

In some embodiments, an initial design of thermal features (such as thermal elements and/or channels described herein) that direct flow of the working fluid across the surface area 326 and/or transfer heat to the working fluid from the surface of the heat-generating component is based on a heat flow map of the surface area. FIG. 4 illustrates a heat flow map 434 of a sub-region 332 of FIG. 3. In some embodiments, creating a heat flow map 434 includes dividing the heat generation map into a plurality of pixels 436 in a two-dimensional embodiment and voxels in a three-dimensional embodiment of the heat flow maps 434. In some embodiments, the heat flow map 434 includes the plurality of pixels 436 with a temperature gradient between the pixels 436.

The temperature gradient between the pixels 436 describes the direction of heat flow from the high-temperature region 430 to a low-temperature region 428. In some embodiments, an initial design of the thermal features (such as thermal elements and/or channels described herein) includes selecting at least some of the pixels as thermal elements (e.g., solid material) to direct working fluid flow and at least some of the pixels 436 to be channels (e.g., voids) that allow working fluid to flow therethrough. In some embodiments, additional initial conditions are defined for the initial design, such as inlet locations, outlet locations, or other initial parameters as will be described herein.

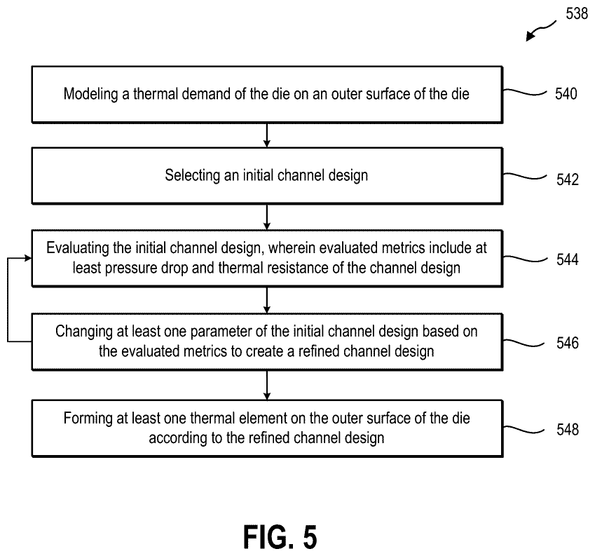

FIG. 5 is a flowchart illustrating an embodiment of a method 538 of manufacturing a thermal management device. In some embodiments, the method 538 includes modeling a thermal management demand of the die on an outer surface of the die at 540. In some embodiments, modeling the thermal management demand includes generating a two-dimensional heat-generation map such as described in relation to FIG. 3. In some embodiments, modeling the thermal management demand includes generating a three-dimensional heat-generation map based at least partially on the topology of the heat-generating device, such as components of the die. In some embodiments, a first processing core and a second processing core have different depths below the outer surface of the die. In some embodiments, the heat-generation map includes depth information to describe the heat-generation within the volume of the die.

In some embodiments, the method 538 further includes selecting an initial channel design at 542. In some embodiments, selecting an initial channel design includes calculating a heat flow map based at least partially on the heat-generation map of the die. In some embodiments, the heat flow map includes a plurality of pixels with a thermal gradient between each of the pixels. In some embodiments, the heat flow map includes a plurality of voxels with a thermal gradient between each of the voxels. In some embodiments, the heat flow map includes a thermal gradient in at least two dimensions of the plurality of voxels.

In some embodiments, selecting an initial channel design includes selecting an initial channel design based at least partially on prioritizing at least one evaluated metric upon which the initial design and/or a refined channel design is evaluated. In some embodiments, the initial design is selected based on providing the least pressure drop (i.e., least flow resistance) across the channel design. For example, an initial design of parallel channels with uniform cross-sectional area along a length thereof provides the least pressure drop. Conversely, an initial channel design with channels having more convoluted shapes, longer lengths, or varying cross-sectional areas along a length thereof increases the pressure drop and resists fluid flow therein. In some embodiments, other evaluated metrics, such as those described below, are prioritized in the initial channel design.

The method 538, in some embodiments, further includes evaluating the initial channel design at 544. In some embodiments, the evaluated metrics include at least pressure drop and thermal resistance of the channel design. For example, the pressure drop between an inlet and an outlet of the channel design is reflective of the required pumping power and/or inlet pressure to flow the working fluid through the cooling volume of the thermal management device. In some embodiments, a lesser pressure drop allows the thermal management device to require less fluid pressure from a pump that delivers working fluid to the thermal management device. In some embodiments, a lesser pressure drop allows for a faster flow of working fluid through the cooling volume of the thermal management device. In some embodiments, a lesser pressure drop allows for a smaller manifold at the inlet of the cooling volume. In some embodiments, a lesser pressure drop allows for thinner walls of the body of the thermal management device.

In some embodiments, the thermal resistance of the channel design is reflective of the rate at which heat is transferred from the surface and/or the thermal elements of the thermal management device to the working fluid. In some embodiments, a lesser thermal resistance allows the working fluid to receive heat from the surface and/or the thermal elements of the die or other surface of the heat-generating component faster. In some embodiments, a lesser thermal resistance allows the working fluid to receive an equal quantity of heat at a higher flow rate of the working fluid through the cooling volume than a higher thermal resistance. In some embodiments, a lesser thermal resistance allows the working fluid to receive an equal quantity of heat at a lower contact surface area-to-volume ratio of the thermal elements and surface contacting the working fluid in the cooling volume than a higher thermal resistance. Less thermal elements and less contact surface(s), in some embodiments, contributes to a lesser pressure drop.

In some embodiments, an average channel length is reflective of the time and/or distance over which the working fluid receives heat from the thermal elements and contact surface of the thermal management device. In some embodiments, a longer channel length allows for a more complete transfer of heat to the working fluid. In some embodiments, a longer channel length increases the pressure drop. In at least one example, a channel design that increases channel length without a substantial increase in pressure drop is desirable.

The method 538 included, in some embodiments, changing at least one parameter of the initial channel design based on the evaluated metrics to create a refined channel design at 546. Changing at least one parameter of the initial channel design improves at least one evaluated metric and, in some embodiments, worsen at least another evaluated metric. In some embodiments, changing at least one parameter of the initial channel design based on the evaluated metrics includes changing at least one parameter of the evaluated metric to improve the worst evaluated metric. For example, an initial channel design of parallel and straight channels allows for a low pressure drop with a short channel length. In some embodiments, the initial channel design includes anastomosing channels. For example, the anastomosing channels allows mixture of working fluid between individual channels while maintaining a net directional flow. In some embodiments, changing at least one parameter of the initial channel design, such as changing an orientation of the channels, increases the channel length by 50% while increasing the pressure drop by a lesser amount.

In some embodiments, the method 538 includes repeating the evaluation of the refined channel design and subsequently changing at least one parameter of the refined channel design to create another refined channel design. The method 538 repeats the evaluation until a change to the evaluated metric(s) ceases to provide a net improvement in the evaluated metrics.

In some embodiments, the method 538 further includes forming at least one thermal element on the outer surface of the die according to the refined channel design at 548. In some embodiments, the refined channel design is the product of any number of iterations through the evaluation of channel designs. In some embodiments, the refined channel design is the final channel design at which a change to the evaluated metric(s) ceases to provide a net improvement in the evaluated metrics.

In some embodiments, forming the at least one thermal element includes forming at least one thermal element in an outer surface of the heat-generating component. In some embodiments, forming at least one thermal element in an outer surface of the heat-generating component includes subtracting material from the outer surface of the heat-generating component, as described in more detail herein. In some embodiments, forming the at least one thermal element includes forming at least one thermal element on an outer surface of the heat-generating component. In some embodiments, forming at least one thermal element on an outer surface of the heat-generating component includes adding material from the outer surface of the heat-generating component, as described in more detail herein. In some embodiments, forming the at least one thermal element includes adding material into a void, recess, or channel formed by subtracting material from an outer surface of the heat-generating component. In at least some embodiments, adding material to the surface of the heat-generating component includes adding a thermal material that is different from a material of the outer surface of the heat-generating component (e.g., a die material).

In some embodiments, the initial channel design and/or refined channel designs include parameters with initial values. In some embodiments, values of at least some of the parameters are changed during the method 538. In some embodiments, the initial values of at least some of the parameters remain fixed during the method 538. In some embodiments, the parameters includes a thermal conductivity of the working fluid, a thermal capacity of the working fluid, a thermal conductivity of the material of the outer surface of the heat-generating component (e.g., die material), a thermal capacity of the material of the outer surface of the heat-generating component (e.g., die material), a thermal conductivity of a thermal element material that may be added to the surface of the heat-generating component, a thermal capacity of a thermal element material that may be added to the surface of the heat-generating component, a quantity and/or position(s) of working fluid inlets, a quantity and/or position(s) of working fluid outlets, channel length, channel orientation, channel pitch, channel depth, channel cross-sectional area, isolation of channels (e.g., branching versus non-branching channels, anastomosing channels), density of thermal elements relative to channel volume and/or open volume to allow working fluid flow therethrough, pressure drop, fluid pump power, or other parameters.

In some embodiments, changing at least one parameter includes changing a position of solid thermal elements in the surface area. For example, the pixels/voxels of a heat generation map (such as the heat generation map described in relation to FIG. 3) and/or the pixels/voxels of a heat flow map (such as the heat flow map described in relation to FIG. 4) may be changed in a channel design between solid material (e.g., at least a portion of a thermal element) and void (e.g., at least a portion of a channel or open portion of the cooling volume). For example, in some embodiments, changing a parameter of the channel design to create a refined channel design (or changing a parameter of the refined channel design to create another refined channel design, etc.) includes changing one or more pixels from solid material to void or from void to solid material.

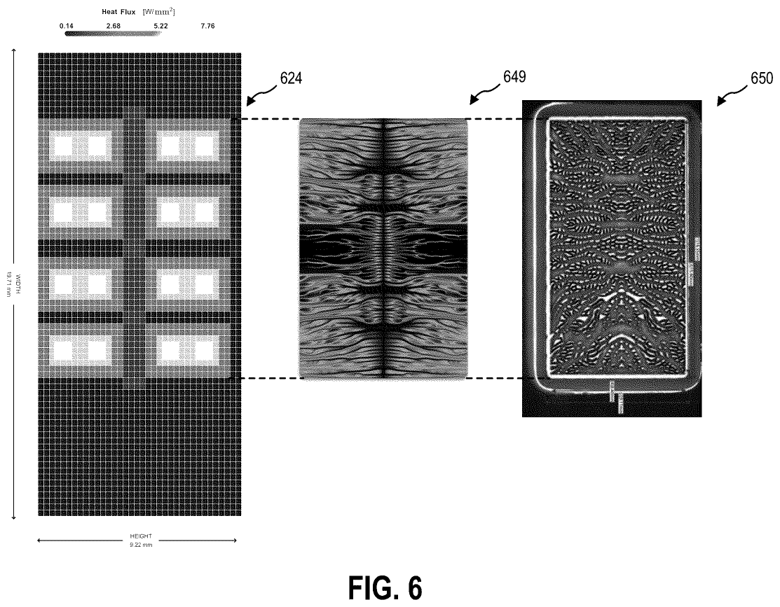

FIG. 6 illustrates such a process of changing one or more pixel(s) of surface area, such as of the heat generation map 624 to produce a refined channel design 649. The embodiment of a refined channel design 649 of FIG. 6 is produced after many cycles of evaluation and changes to the parameters of the initial channel design. In the illustrated embodiment of FIG. 6, the darker regions are associated with areas of cooler working fluid, and the lighter regions are associated with areas of hotter working fluid, allowing the removal of heat from the heat-generation component. When the change(s) to the refined channel design cease to improve the evaluated metrics of the refined channel design, the refined channel design is formed in a surface 650 of the heat-generating component to direct flow of working fluid across the surface 650.

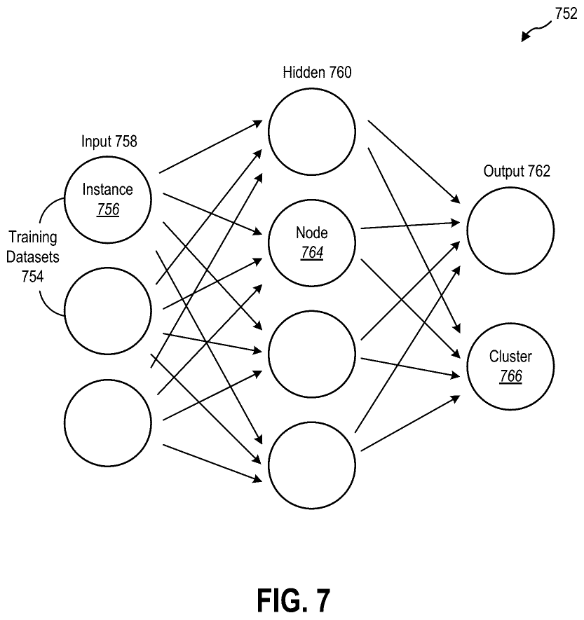

In some embodiments, the change(s) to the parameter and the evaluation of the channel design is performed at least partially by a machine learning model. FIG. 7 is a schematic illustration of an embodiment of a neural network 752. In some embodiments, the neural network 752 has a plurality of layers with an input layer 758 configured to receive at least one input training dataset 754 or input training instance 756 and an output layer 762, with a plurality of additional or hidden layers 760 therebetween. The training datasets can be input into the neural network to train the neural network and identify individual and combinations of labels or attributes of the training instances. In some embodiments, the neural network can receive multiple training datasets concurrently and learn from the different training datasets simultaneously. In some embodiments, the training dataset(s) include channel designs with known parameters and known values of evaluated metrics. In some embodiments, the training dataset(s) include channel designs with known parameters and at least some known values of evaluated metrics. In some embodiments, the training dataset(s) include channel designs with known parameters and unknown values of evaluated metrics. While the illustrated embodiment includes a limited quantity of nodes 764, it should be understood that, in some embodiments, a neural network has millions, billions, or more of nodes 764 in the input layer 758, hidden layers 760, output layer 762, or combination thereof.

In some embodiments, the machine learning system includes a plurality of machine learning models that operate together. Each of the machine learning models has a plurality of hidden layers 760 between the input layer 758 and the output layer 762. The hidden layers 760 have a plurality of input nodes (e.g., nodes 764), where each of the nodes 764 operates on the received inputs from the previous layer. In a specific example, a first hidden layer 760 has a plurality of nodes and each of the nodes performs an operation on each instance from the input layer 758. Each node of the first hidden layer 760 provides a new input into each node of the second hidden layer, which, in turn, performs a new operation on each of those inputs. The nodes of the second hidden layer then passes outputs, such as identified clusters 766, to the output layer 762.

In some embodiments, each of the nodes 764 has a linear function and an activation function. The linear function may attempt to optimize or approximate a solution with a line of best fit, such as reduced pressure drop or reduce thermal resistance. The activation function operates as a test to check the validity of the linear function. In some embodiments, the activation function produces a binary output that determines whether the output of the linear function is passed to the next layer of the machine learning model. In this way, the machine learning system can limit and/or prevent the propagation of poor fits to the data and/or non-convergent solutions.

The machine learning model includes an input layer that receives at least one training dataset. In some embodiments, at least one machine learning model uses supervised training. In some embodiments, at least one machine learning model uses unsupervised training. Unsupervised training can be used to draw inferences and find patterns or associations from the training dataset(s) without known outputs. In some embodiments, unsupervised learning can identify clusters of similar labels or characteristics for a variety of training instances and allow the machine learning system to extrapolate the performance of instances with similar characteristics.

In some embodiments, semi-supervised learning can combine benefits from supervised learning and unsupervised learning. As described herein, the machine learning system can identify associated labels or characteristic between instances, which may allow a training dataset with known outputs and a second training dataset including more general input information to be fused. Unsupervised training can allow the machine learning system to cluster the instances from the second training dataset without known outputs and associate the clusters with known outputs from the first training dataset. The values of the output layer, in some embodiments, are compared to known values of training instances, and parameters associated with each node of the hidden layer(s) allow back propagation through the neural network to refine and train the neural network.

While a neural network 752 is described in relation to FIG. 7, in some embodiments, other machine learning models and/or systems are used to evaluated and refine the channel design. In some embodiments, the machine learning model and/or system includes diffusion limited algorithms. In some embodiments, the machine learning model and/or system includes constructal theory models.

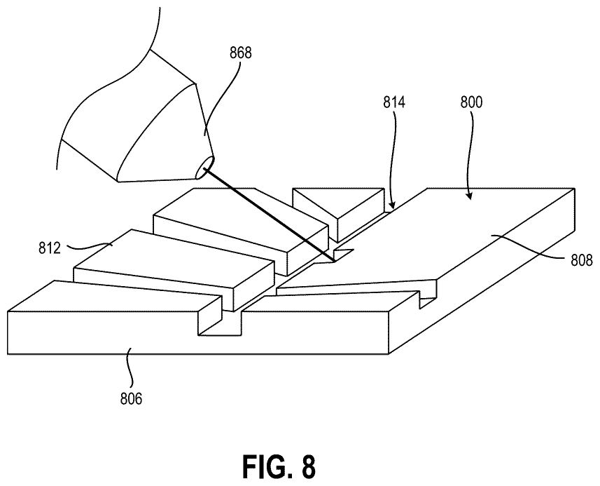

As described herein, methods and systems according to the present disclosure include forming at least one thermal element in or on a surface of a heat-generating component and/or the thermal management device. FIG. 8 illustrates an embodiment of a subtractive manufacturing process. In some embodiments, the thermal management device 800 includes a plurality of thermal elements 812 that define one or more channels 814 in the outer surface 808 of the heat-generating component 806. In some embodiments, material is removed from the outer surface 808 of the heat-generating component 806 or another surface of the thermal management device 800 by laser 868 etching and/or ablation. In some embodiments, material is removed from the outer surface 808 of the heat-generating component 806 or another surface of the thermal management device 800 by chemical etching, lithography (e.g., photolithography or e-beam lithography), skiving, or combinations thereof.

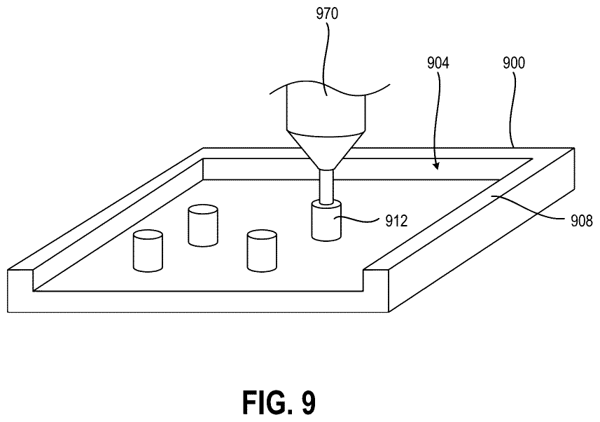

FIG. 9 illustrates an embodiment of an additive manufacturing process. In some embodiments, an additive manufacturing process adds material to the outer surface 908 of the heat-generating component 906 or another surface of the thermal management device 900. In some embodiments, the added material is the same material as that of the outer surface 908 of the heat-generating component 906 (e.g., die material) or another surface of the thermal management device 900. In some embodiments, the added material is a thermal material that is different from that of the outer surface 908 of the heat-generating component 906 (e.g., die material) or another surface of the thermal management device 900. In some examples, a thermal material that is different from that of the outer surface 908 of the heat-generating component 906 or another surface of the thermal management device 900 allows the thermal elements 912 in the cooling volume 904 and/or between the channels to have different thermal properties than the die material, other material of the outer surface 908 of the heat-generating component 906 (e.g., die material), or another surface of the thermal management device 900.

In some embodiments, the material is added by a focused ion beam 970 to deposit material. In some embodiments, material is added to the thermal management device 900 by selective laser melting or selective laser sintering. In some embodiments, material is added to the thermal management device 900 by lamination of material. In some embodiments, material is added to the thermal management device 900 by polymerization, such as photo-polymerization. In some embodiments, material is added to the thermal management device 900 by ion sputtering. In some embodiments, material is extruded onto the outer surface 908 of the heat-generating component 906 or another surface of the thermal management device 900.

In some embodiments, material is added through an additive process and a portion of the material is removed through a subtractive process to form the thermal element 912. In some embodiments, material is removed through a subtractive process to produce a cooling volume 904, channel, or other void into which material is subsequently added to form a thermal element 912.

In at least some embodiments according to the present disclosure, methods of designing, manufacturing, and operating a thermal management device can provide a more efficient flow of working fluid across a surface of a heat-generating component.

### INDUSTRIAL APPLICABILITY

The present disclosure relates to the design, manufacturing, and operation of a thermal management device with a working fluid that receives heat from a heat-generating component. The working fluid flows away from the heat-generating component and carries the heat away from the heat-generating component. In at least one example, the working fluid is a liquid working fluid that receives heat from the heat-generating component at a thermal interface, and the liquid working fluid flows away from the thermal management device to a heat exchanger or other device to exhaust the heat from the liquid working fluid to atmosphere or other heat dump.

In some embodiments, at least a portion of the thermal management device is integrally formed with the heat-generating component. In some embodiments, the thermal management device is integrally formed with a surface of the heat-generating component. In some examples, the thermal management device is formed in a surface of the heat-generated component through a subtractive process to remove material from the surface of the heat-generating component and/or form one or more thermal elements in the surface of the heat-generating component. In some examples, the thermal management device is formed on a surface of the heat-generating component through an additive process to adhere, sinter, or otherwise bond thermal elements to the surface of the heat-generating component. In some embodiments, the thermal management device is formed through a combination of subtractive and additive processes, such as removing material from a surface of the heat-generating component and adhering, sintering, or otherwise bonding material to the outer surface (or the exposed surface after removing material from the outer surface) to form one or more thermal elements in or on the surface of the heat-generating component.

In some embodiments, the thermal management device is thermally connected to a heat-generating component. As used herein, the term “thermally connected” refers to a connection between two components that facilitates the transfer of heat between the two components. Two thermally connected components may be in direct contact (e.g., without any intervening material). Two thermally connected components may have one or more thermal connectors between them. The thermal connector may be a thermally conductive material, or a material that facilitates the transfer of heat through its mass. For example, two thermally connected components may include a thermal interface material (TIM) between the two components. A TIM may be a material, such as a flowable paste formed from thermally conductive materials, that may be inserted between two components to reduce or eliminate the presence of air gaps and other insulating material. In some embodiments, two thermally connected components may be separated from each other. For example, a thermal connector such as a heat pipe may thermally connect two components across a distance.

In some embodiments, the one or more thermal elements are formed in or on the thermal management device based at least partially on a flow design or schema generated from a thermal demand map. In some embodiments, a heat-generating component produces heat in a non-uniform distribution at the outer surface of the heat-generating component. The thermal elements positioned in or on the surface of the heat-generating component are positioned to efficiently remove the heat produced at the surface of the heat-generating component. In some embodiments, one or more channels formed by or between the thermal elements direct a working fluid across the surface and/or away from the surface to remove heat from the hotter portions of the surface and/or toward cooler portions of the surface. In some embodiments, one or more channels formed by or between the thermal elements direct a working fluid across the surface through a cooling volume from an inlet to an outlet of the cooling volume. In some examples, the inlet and outlet are defined by a working fluid manifold positioned on or integrated in the thermal management device.

In some embodiments, a heat-generating component is a processing unit. A processing unit includes a central processing unit, a graphics processing unit, a physics processing unit, a network processing unit, an audio processing unit, or other processing units including one or more processing cores, volatile memory (e.g., cache), non-volatile memory, input-output (I/O) components, or other components of the processing units. The components of the processing unit produce heat. The amount of heat and the dispersion of the heat at the surface varies according to the topology of the components of the processing unit. A heat-generation map of the outer surface of the heat-generating component can allow for efficient design and construction of a thermal management device for the heat-generating component.

While the present disclosure describes embodiments of thermal management devices in relation to processing units, it should be understood that the embodiments of systems and methods for designing, manufacturing, operating, and combinations thereof thermal management devices are applicable to other heat-generating components, such as power supplies, computer system memory (volatile and non-volatile), networking devices, motherboard components, communication bridges, etc.

In at least some embodiments, a thermal management device includes a cooling volume that is a microfluidic volume in or on an outer surface of a processing unit die and/or between a first die and a second die of a stacked-die processing unit. In some embodiments, a thermal management device is thermally connected to and/or integrated with a 2.5D processing unit in which the microfluidic volume is positioned in or on an upper surface of a die of a processing unit.

In some embodiments, the thermal management device includes a working fluid positioned in a cooling volume contacting or thermally connected to a heat-generating component. In some embodiments, the cooling volume is contacting an outer surface of the heat-generating component. In some embodiments, the cooling volume is substantially enclosed within a body of the thermal management device, where the body thermally connects the cooling volume to an outer surface of the heat-generating component. In some embodiments, the body is thermally connected to an outer surface of the heat-generating component by a TIM.

In some embodiments, the thermal management device includes and/or is integrated with the outer surface of the heat-generating component. For example, the body of the thermal management device defines a portion of the cooling volume, and the outer surface of the heat-generating component defines another portion of the cooling volume. The thermal management device, therefore, in some embodiments, includes one or more thermal elements located in or on the surface of the heat-generating component. In some embodiments, one or more thermal elements, such as pins, fins, rods, or other positive thermal elements are positioned on an outer surface of the heat-generating component. In some embodiments, one or more channels, recesses, voids, or other negative thermal elements between pins, fins, rods, etc., are positioned in an outer surface of the heat-generating component. In some embodiments, one or more positive thermal elements are positioned in the negative thermal elements. For example, a plurality of parallel channels (e.g., negative thermal elements) etched in the outer surface define fins or other positive thermal elements therebetween without adding material to the outer surface of the heat-generating component.

In some embodiments, a thermal management device is thermally connected to and/or integrated with a 3D heat-generating component (i.e., processing unit) in which the microfluidic cooling volume is positioned in or on an upper surface of a first die of the 3D heat-generating component and in or on a lower surface of a second die of the 3D heat-generating component.

In some embodiments, the cooling volume is substantially enclosed within the 3D heat-generating component between the first die and the second die. In some embodiments, the cooling volume includes one or more thermal elements located in or on the upper surface of a first die of the 3D heat-generating component and/or in or on a lower surface of a second die of the 3D heat-generating component. In some embodiments, a first thermal element located in or on the upper surface of a first die of the 3D heat-generating component contacts a second thermal element located in or on a lower surface of a second die of the 3D heat-generating component to form a closed channel. In some embodiments, a first thermal element located in or on the upper surface of a first die of the 3D heat-generating component and/or a second thermal element located in or on a lower surface of a second die of the 3D heat-generating component protrude into an open portion of the cooling volume without contacting one another, allowing working fluid to flow between the first thermal element and the second thermal element in the cooling volume while the first thermal element and the second thermal element direct flow of the working fluid relative to the upper surface of a first die of the 3D heat-generating component and/or the lower surface of a second die of the 3D heat-generating component, respectively.

In some embodiments, the working fluid of the thermal management device (of any other embodiments of a thermal management device described herein) is a liquid working fluid. In some embodiments, the working fluid is a gaseous working fluid. In some embodiments, the working fluid is a substantially single-phase working fluid. For example, a single-phase working fluid remains in a single physical phase (e.g., a liquid) throughout the operation of the thermal management device. In some embodiments, the working fluid is a two-phase working fluid. For example, a two-phase working fluid transitions between physical phases (e.g., liquid to gas; gas to liquid) as heat is received or exhaust from the working fluid during operation of the thermal management device.

As described herein, a system and method of designing and manufacturing the thermal elements of a thermal management device, according to at least some embodiments of the present disclosure, includes creating a heat generation map of the heat-generating component.

In some embodiments, the heat generation map maps the heat generation of a heat-generating component (such as any embodiment of heat-generating components described herein) across a surface area of the heat-generating component. In some examples, the surface area is that of an outer surface of the heat-generating component, such as described herein. In some examples, the surface area is an upper surface or lower surface of the heat-generating component or portion of the heat-generating component, such as described herein. In some embodiments, the heat generation map includes low-temperature regions and high-temperature regions. It should be understood that low-temperature and high-temperature are considered relative to one another, and, depending on the demands and operating conditions of a heat-generating component, the nominal temperature of low-temperature regions and high-temperature regions can vary.

In some embodiments, a thermal management device flows a working fluid across the surface of the heat-generating component to move heat from the high-temperature regions toward the low-temperature regions. The working fluid thereby reduces the temperature of the high-temperature regions. The working fluid is circulated to the surface area of the heat-generating component through one or more inlets of the thermal management device and circulated from the surface area of the heat-generating component through one or more outlets of the thermal management device. In some embodiments, the thermal management device flows a working fluid from the one or more inlets, across the surface of the heat-generating component to move heat from the high-temperature regions toward the low-temperature regions, and out through the one or more outlets.

In some embodiments, mapping or modeling a thermal management demand of the heat-generating component includes creating or obtaining a power consumption map of the heat-generating component. For example, different cores, memory, connections, or components of the heat-generating component consume different amounts of power during operation. In some embodiments, the heat generation of the heat-generating component is proportional to the power consumption of the different regions or components of the heat-generating component. A power consumption map allows for a calculation or approximation of heat generation during operation.

In some embodiments, an initial design of thermal features (such as thermal elements and/or channels described herein) that direct flow of the working fluid across the surface area and/or transfer heat to the working fluid from the surface of the heat-generating component is based on a heat flow map of the surface area. In some embodiments, creating a heat flow map includes dividing the heat generation map into a plurality of pixels in a two-dimensional embodiment and voxels in a three-dimensional embodiment of the heat flow maps. In some embodiments, the heat flow map includes the plurality of pixels with a temperature gradient between the pixels.

The temperature gradient between the pixels describes the direction of heat flow from the high-temperature region to a low-temperature region. In some embodiments, an initial design of the thermal features (such as thermal elements and/or channels described herein) includes selecting at least some of the pixels as thermal elements (e.g., solid material) to direct working fluid flow and at least some of the pixels to be voids (e.g., channels) that allow working fluid to flow therethrough. In some embodiments, additional initial conditions are defined for the initial design, such as inlet locations, outlet locations, or other initial parameters as will be described herein.

In some embodiments, a method of manufacturing a thermal management device includes modeling a thermal management demand of the die on an outer surface of the die. In some embodiments, modeling the thermal management demand includes generating a two-dimensional heat-generation map such as described herein. In some embodiments, modeling the thermal management demand includes generating a three-dimensional heat-generation map based at least partially on the topology of the heat-generating device, such as components of the die. In some embodiments, a first processing core and a second processing core have different depths below the outer surface of the die. In some embodiments, the heat-generation map includes depth information to describe the heat-generation within the volume of the die.

In some embodiments, the method further includes selecting an initial channel design. In some embodiments, selecting an initial channel design includes calculating a heat flow map based at least partially on the heat-generation map of the die. In some embodiments, the heat flow map includes a plurality of pixels with a thermal gradient between each of the pixels. In some embodiments, the heat flow map includes a plurality of voxels with a thermal gradient between each of the voxels. In some embodiments, the heat flow map includes a thermal gradient in at least two dimensions of the plurality of voxels.

In some embodiments, selecting an initial channel design includes selecting an initial channel design based at least partially on prioritizing at least one evaluated metric upon which the initial design and/or a refined channel design is evaluated. In some embodiments, the initial design is selected based on providing the least pressure drop (i.e., least flow resistance) across the channel design. For example, an initial design of parallel channels with uniform cross-sectional area along a length thereof provides the least pressure drop. Conversely, an initial channel design with channels having more convoluted shapes, longer lengths, or varying cross-sectional areas along a length thereof increases the pressure drop and resists fluid flow therein. In some embodiments, other evaluated metrics, such as those described below, are prioritized in the initial channel design.

The method, in some embodiments, further includes evaluating the initial channel design. In some embodiments, the evaluated metrics include at least pressure drop and thermal resistance of the channel design. For example, the pressure drop between an inlet and an outlet of the channel design is reflective of the required pumping power and/or inlet pressure to flow the working fluid through the cooling volume of the thermal management device. In some embodiments, a lesser pressure drop allows the thermal management device to require less fluid pressure from a pump that delivers working fluid to the thermal management device. In some embodiments, a lesser pressure drop allows for a faster flow of working fluid through the cooling volume of the thermal management device. In some embodiments, a lesser pressure drop allows for a smaller manifold at the inlet of the cooling volume. In some embodiments, a lesser pressure drop allows for thinner walls of the body of the thermal management device.

In some embodiments, the thermal resistance of the channel design is reflective of the rate at which heat is transferred from the surface and/or the thermal elements of the thermal management device to the working fluid. In some embodiments, a lesser thermal resistance allows the working fluid to receive heat from the surface and/or the thermal elements of the die or other surface of the heat-generating component faster. In some embodiments, a lesser thermal resistance allows the working fluid to receive an equal quantity of heat at a higher flow rate of the working fluid through the cooling volume than a higher thermal resistance. In some embodiments, a lesser thermal resistance allows the working fluid to receive an equal quantity of heat at a lower contact surface area-to-volume ratio of the thermal elements and surface contacting the working fluid in the cooling volume than a higher thermal resistance. Less thermal elements and less contact surface(s), in some embodiments, contributes to a lesser pressure drop.

In some embodiments, an average channel length is reflective of the time and/or distance over which the working fluid receives heat from the thermal elements and contact surface of the thermal management device. In some embodiments, a longer channel length allows for a more complete transfer of heat to the working fluid. In some embodiments, a longer channel length increases the pressure drop. In at least one example, a channel design that increases channel length without a substantial increase in pressure drop is desirable.

The method included, in some embodiments, changing at least one parameter of the initial channel design based on the evaluated metrics to create a refined channel design. Changing at least one parameter of the initial channel design improves at least one evaluated metric and, in some embodiments, worsen at least another evaluated metric. In some embodiments, changing at least one parameter of the initial channel design based on the evaluated metrics includes changing at least one parameter of the evaluated metric to improve the worst evaluated metric. For example, an initial channel design of parallel and straight channels allows for a low pressure drop with a short channel length. In some embodiments, the initial channel design includes anastomosing channels. For example, the anastomosing channels allows mixture of working fluid between individual channels while maintaining a net directional flow. In some embodiments, changing at least one parameter of the initial channel design, such as changing an orientation of the channels, increases the channel length by 50% while increasing the pressure drop by a lesser amount.

In some embodiments, the method includes repeating the evaluation of the refined channel design and subsequently changing at least one parameter of the refined channel design to create another refined channel design. The method repeats the evaluation until a change to the evaluated metric(s) ceases to provide a net improvement in the evaluated metrics.

In some embodiments, the method further includes forming at least one thermal element on the outer surface of the die according to the refined channel design. In some embodiments, the refined channel design is the product of any number of iterations through the evaluation of channel designs. In some embodiments, the refined channel design is the final channel design at which a change to the evaluated metric(s) ceases to provide a net improvement in the evaluated metrics.

In some embodiments, forming the at least one thermal element includes forming at least one thermal element in an outer surface of the heat-generating component. In some embodiments, forming at least one thermal element in an outer surface of the heat-generating component includes subtracting material from the outer surface of the heat-generating component, as described in more detail herein. In some embodiments, forming the at least one thermal element includes forming at least one thermal element on an outer surface of the heat-generating component. In some embodiments, forming at least one thermal element on an outer surface of the heat-generating component includes adding material from the outer surface of the heat-generating component, as described in more detail herein. In some embodiments, forming the at least one thermal element includes adding material into a void, recess, or channel formed by subtracting material from an outer surface of the heat-generating component. In at least some embodiments, adding material to the surface of the heat-generating component includes adding a thermal material that is different from a material of the outer surface of the heat-generating component (e.g., a die material).

In some embodiments, the initial channel design and/or refined channel designs include parameters with initial values. In some embodiments, values of at least some of the parameters are changed during the method. In some embodiments, the initial values of at least some of the parameters remain fixed during the method. In some embodiments, the parameters includes a thermal conductivity of the working fluid, a thermal capacity of the working fluid, a thermal conductivity of the material of the outer surface of the heat-generating component (e.g., die material), a thermal capacity of the material of the outer surface of the heat-generating component (e.g., die material), a thermal conductivity of a thermal element material that may be added to the surface of the heat-generating component, a thermal capacity of a thermal element material that may be added to the surface of the heat-generating component, a quantity and/or position(s) of working fluid inlets, a quantity and/or position(s) of working fluid outlets, channel length, channel orientation, channel pitch, channel depth, channel cross-sectional area, isolation of channels (e.g., branching versus non-branching channels, anastomosing channels), density of thermal elements relative to channel volume and/or open volume to allow working fluid flow therethrough, pressure drop, fluid pump power, or other parameters.

In some embodiments, changing at least one parameter includes changing a position of solid thermal elements in the surface area. For example, the pixels/voxels of a heat generation map (such as the heat generation map described herein) and/or the pixels/voxels of a heat flow map (such as the heat flow map described herein) may be changed in a channel design between solid material (e.g., at least a portion of a thermal element) and void (e.g., at least a portion of a channel or open portion of the cooling volume). For example, in some embodiments, changing a parameter of the channel design to create a refined channel design (or changing a parameter of the refined channel design to create another refined channel design, etc.) includes changing one or more pixels from solid material to void or from void to solid material.

In some embodiments, the change(s) to the parameter and the evaluation of the channel design is performed at least partially by a machine learning model. In some embodiments, the machine learning model includes or is a neural network. In some embodiments, the neural network has a plurality of layers with an input layer configured to receive at least one input training dataset or input training instance and an output layer, with a plurality of additional or hidden layers therebetween. The training datasets can be input into the neural network to train the neural network and identify individual and combinations of labels or attributes of the training instances. In some embodiments, the neural network can receive multiple training datasets concurrently and learn from the different training datasets simultaneously. In some embodiments, the training dataset(s) include channel designs with known parameters and known values of evaluated metrics. In some embodiments, the training dataset(s) include channel designs with known parameters and at least some known values of evaluated metrics. In some embodiments, the training dataset(s) include channel designs with known parameters and unknown values of evaluated metrics. While the illustrated embodiment includes a limited quantity of nodes, it should be understood that, in some embodiments, a neural network has millions, billions, or more of nodes in the input layer, hidden layers, output layer, or combination thereof.

In some embodiments, the machine learning system includes a plurality of machine learning models that operate together. Each of the machine learning models has a plurality of hidden layers between the input layer and the output layer. The hidden layers have a plurality of input nodes (e.g., nodes), where each of the nodes operates on the received inputs from the previous layer. In a specific example, a first hidden layer has a plurality of nodes and each of the nodes performs an operation on each instance from the input layer. Each node of the first hidden layer provides a new input into each node of the second hidden layer, which, in turn, performs a new operation on each of those inputs. The nodes of the second hidden layer then passes outputs, such as identified clusters, to the output layer.

In some embodiments, each of the nodes has a linear function and an activation function. The linear function may attempt to optimize or approximate a solution with a line of best fit, such as reduced pressure drop or reduce thermal resistance. The activation function operates as a test to check the validity of the linear function. In some embodiments, the activation function produces a binary output that determines whether the output of the linear function is passed to the next layer of the machine learning model. In this way, the machine learning system can limit and/or prevent the propagation of poor fits to the data and/or non-convergent solutions.

The machine learning model includes an input layer that receives at least one training dataset. In some embodiments, at least one machine learning model uses supervised training. In some embodiments, at least one machine learning model uses unsupervised training. Unsupervised training can be used to draw inferences and find patterns or associations from the training dataset(s) without known outputs. In some embodiments, unsupervised learning can identify clusters of similar labels or characteristics for a variety of training instances and allow the machine learning system to extrapolate the performance of instances with similar characteristics.

In some embodiments, semi-supervised learning can combine benefits from supervised learning and unsupervised learning. As described herein, the machine learning system can identify associated labels or characteristic between instances, which may allow a training dataset with known outputs and a second training dataset including more general input information to be fused. Unsupervised training can allow the machine learning system to cluster the instances from the second training dataset without known outputs and associate the clusters with known outputs from the first training dataset. The values of the output layer, in some embodiments, are compared to known values of training instances, and parameters associated with each node of the hidden layer(s) allow back propagation through the neural network to refine and train the neural network.

While a neural network is described herein, in some embodiments, other machine learning models and/or systems are used to evaluated and refine the channel design. In some embodiments, the machine learning model and/or system includes diffusion limited algorithms. In some embodiments, the machine learning model and/or system includes constructal theory models.

As described herein, methods and systems according to the present disclosure include forming at least one thermal element in or on a surface of a heat-generating component and/or the thermal management device. In some embodiments, the thermal management device includes a plurality of thermal elements that define one or more channels in the outer surface of the heat-generating component. In some embodiments, material is removed from the outer surface of the heat-generating component or another surface of the thermal management device by laser etching and/or ablation. In some embodiments, material is removed from the outer surface of the heat-generating component or another surface of the thermal management device by chemical etching, lithography (e.g., photolithography or e-beam lithography), skiving, or combinations thereof.

In some embodiments, an additive manufacturing process adds material to the outer surface of the heat-generating component or another surface of the thermal management device. In some embodiments, the added material is the same material as that of the outer surface of the heat-generating component (e.g., die material) or another surface of the thermal management device. In some embodiments, the added material is a thermal material that is different from that of the outer surface of the heat-generating component (e.g., die material) or another surface of the thermal management device. In some examples, a thermal material that is different from that of the outer surface of the heat-generating component or another surface of the thermal management device allows the thermal elements in the cooling volume and/or between the channels to have different thermal properties than the die material, other material of the outer surface of the heat-generating component (e.g., die material), or another surface of the thermal management device.

In some embodiments, the material is added by a focused ion beam to deposit material. In some embodiments, material is added to the thermal management device by selective laser melting or selective laser sintering. In some embodiments, material is added to the thermal management device by lamination of material. In some embodiments, material is added to the thermal management device by polymerization, such as photo-polymerization. In some embodiments, material is added to the thermal management device by ion sputtering. In some embodiments, material is extruded onto the outer surface of the heat-generating component or another surface of the thermal management device.

In some embodiments, material is added through an additive process and a portion of the material is removed through a subtractive process to form the thermal element. In some embodiments, material is removed through a subtractive process to produce a cooling volume, channel, or other void into which material is subsequently added to form a thermal element.

In at least some embodiments according to the present disclosure, methods of designing, manufacturing, and operating a thermal management device can provide a more efficient flow of working fluid across a surface of a heat-generating component.

The present disclosure relates to systems and methods for the design, manufacturing, and operation of thermal management devices according to at least the examples provided in the clauses below:

Clause 1. A method for manufacturing a thermal management device, the method comprising: modeling a thermal management demand of a heat-generating component on an outer surface of the heat-generating component as a heat generation map; selecting an initial channel design based on the heat generation map; evaluating the initial channel design, wherein evaluated metrics include at least pressure drop and thermal resistance of the channel design; changing at least one parameter of the initial channel design based on the evaluated metrics to create a refined channel design; and forming at least one thermal element in or on the outer surface of the heat-generating component according to the refined channel design.

Clause 2. The method of clause 1, wherein the initial channel design includes an inlet position.

Clause 3. The method of clause 1, wherein the initial channel design includes an outlet position.

Clause 4. The method of clause 1 or 2, wherein the initial channel design includes a channel length.

Clause 5. The method of any preceding clause, wherein the initial channel design includes a channel pitch.

Clause 6. The method of any preceding clause, wherein modeling a thermal demand of the heat-generating component includes mapping a power consumption map of components of the heat-generating component to the outer surface of the heat-generating component.

Clause 7. The method of any preceding clause, wherein each channel of a plurality of channels of the initial channel design has an equal channel length.

Clause 8. The method of any preceding clause, wherein forming at least one thermal element on the outer surface of the heat-generating component according to the refined channel design includes removing die material from the outer surface of the heat-generating component.

Clause 9. The method of any preceding clause, wherein forming at least one thermal element on the outer surface of the heat-generating component according to the refined channel design includes adding thermal element material to the outer surface of the heat-generating component.

Clause 10. The method of clause 9, wherein the thermal element material is different from a heat-generating component material of the heat-generating component.

Clause 11. The method of clause 1, wherein forming at least one thermal element on the outer surface of the heat-generating component according to the refined channel design includes removing heat-generating component material from the outer surface of the heat-generating component and adding thermal element material to the heat-generating component.

Clause 12. The method of any preceding clause, wherein the initial channel design includes anastomosing channels.

Clause 13. The method of any preceding clause, wherein evaluating the initial channel design and changing at least one parameter of the initial channel design based on the evaluated metrics includes using a machine learning model to change the at least one parameter.

Clause 14. The method of clause 13, wherein the machine learning model includes a constructal theory model.

Clause 15. The method of clause 13, wherein the machine learning model includes a diffusion limited algorithm.

Clause 16. A device for thermal management comprising: a heat-generating component having an outer surface; a body connected to the heat-generating component; a microfluidic cooling volume contacting the outer surface and defined by the outer surface and the body; and at least one microfluidic thermal element positioned on the outer surface according to a channel design based at least partially on a heat generation map of the outer surface and in the microfluidic volume to transfer heat from the heat-generating component to a working fluid in the microfluidic volume.

Clause 17. The device of clause 16, wherein the microfluidic thermal element is a positive thermal element.

Clause 18. The device of clause 16, wherein the microfluidic thermal element is a negative thermal element.

Clause 19. The device of any of clauses 16-18, further comprising a pump that flows the working fluid to the microfluidic cooling volume.

Clause 20. A method for manufacturing a processing unit, the method comprising: modeling a thermal management demand of a processing unit on an outer surface of a die of the processing unit as a heat generation map; selecting an initial channel design for the outer surface of the die; evaluating the initial channel design, wherein evaluated metrics of the initial channel design include at least pressure drop and thermal resistance of the initial channel design; changing at least one parameter of the initial channel design based on the evaluated metrics to create a refined channel design; evaluating the refined channel design, wherein evaluated metrics of the refined channel design include at least pressure drop and thermal resistance of the refined channel design; changing at least one parameter of the refined channel design based on the evaluated metrics of the refined channel design to create another refined channel design; and forming at least one thermal element in or on the outer surface of the die according to the another refined channel design.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the scope of the present disclosure, and that various changes, substitutions, and alterations may be made to embodiments disclosed herein without departing from the scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method for manufacturing a thermal management device, the method comprising:
modeling a thermal management demand of a heat-generating component on an outer surface of the heat-generating component as a heat generation map;
selecting an initial channel design based on the heat generation map;
evaluating the initial channel design, wherein evaluated metrics include at least pressure drop and thermal resistance of the channel design;
changing at least one parameter of the initial channel design based on the evaluated metrics to create a refined channel design; and
forming at least one thermal element in or on the outer surface of the heat-generating component according to the refined channel design.

2. The method of claim 1, wherein the initial channel design includes an inlet position.

3. The method of claim 1, wherein the initial channel design includes an outlet position.

4. The method of claim 1, wherein the initial channel design includes a channel length.

5. The method of claim 1, wherein the initial channel design includes a channel pitch.

6. The method of claim 1, wherein modeling a thermal demand of the heat-generating component includes mapping a power consumption map of components of the heat-generating component to the outer surface of the heat-generating component.

7. The method of claim 1, wherein each channel of a plurality of channels of the initial channel design has an equal channel length.

8. The method of claim 1, wherein forming at least one thermal element on the outer surface of the heat-generating component according to the refined channel design includes removing die material from the outer surface of the heat-generating component.

9. The method of claim 1, wherein forming at least one thermal element on the outer surface of the heat-generating component according to the refined channel design includes adding thermal element material to the outer surface of the heat-generating component.

10. The method of claim 9, wherein the thermal element material is different from a heat-generating component material of the heat-generating component.

11. The method of claim 1, wherein forming at least one thermal element on the outer surface of the heat-generating component according to the refined channel design includes removing heat-generating component material from the outer surface of the heat-generating component and adding thermal element material to the heat-generating component.

12. The method of claim 1, wherein the initial channel design includes anastomosing channels.

13. The method of claim 1, wherein evaluating the initial channel design and changing at least one parameter of the initial channel design based on the evaluated metrics includes using a machine learning model to change the at least one parameter.

14. The method of claim 13, wherein the machine learning model includes a constructal theory model.

15. The method of claim 13, wherein the machine learning model includes a diffusion limited algorithm.

16. A device for thermal management comprising:
a heat-generating component having an outer surface;
a body connected to the heat-generating component;
a microfluidic cooling volume contacting the outer surface and defined by the outer surface and the body; and
at least one microfluidic thermal element positioned on the outer surface according to a channel design based at least partially on a heat generation map of the outer surface and in the microfluidic volume to transfer heat from the heat-generating component to a working fluid in the microfluidic volume.

17. The device of claim 16, wherein the microfluidic thermal element is a positive thermal element.

18. The device of claim 16, wherein the microfluidic thermal element is a negative thermal element.

19. The device of claim 16, further comprising a pump that flows the working fluid to the microfluidic cooling volume.

20. A method for manufacturing a processing unit, the method comprising:
modeling a thermal management demand of a processing unit on an outer surface of a die of the processing unit as a heat generation map;
selecting an initial channel design for the outer surface of the die;
evaluating the initial channel design, wherein evaluated metrics of the initial channel design include at least pressure drop and thermal resistance of the initial channel design;
changing at least one parameter of the initial channel design based on the evaluated metrics to create a refined channel design;
evaluating the refined channel design, wherein evaluated metrics of the refined channel design include at least pressure drop and thermal resistance of the refined channel design;
changing at least one parameter of the refined channel design based on the evaluated metrics of the refined channel design to create another refined channel design; and
forming at least one thermal element in or on the outer surface of the die according to the another refined channel design.
